(19) United States
(12) Patent Application Publication
(10) Pub. No.: US 2026/0239716 A1
(43) Pub. Date: Aug. 13, 2026

(54) SEMICONDUCTOR DEVICE AND MANUFACTURING METHOD THEREOF

(71) Applicant: Shanghai Huali Integrated Circuit Corporation, Shanghai (CN)

(72) Inventors: Qiwei WANG, Shanghai (CN); Zhigang ZHANG, Shanghai (CN)

(73) Assignee: Shanghai Huali Integrated Circuit Corporation, Shanghai (CN)

(21) Appl. No.: 19/232,909

(22) Filed: Jun. 10, 2025

(30) Foreign Application Priority Data
Feb. 7, 2025 (CN) 2025101387452

(51) Int. Cl. H10D 84/01; H10D 84/83; H10K 59/12

(52) U.S. Cl. CPC H10D 84/013; H10D 84/0142; H10D 84/0156; H10D 84/8312; H10D 84/83138; H10K 59/12

(57) ABSTRACT

A semiconductor device and a manufacturing method thereof are provided. The method comprises: providing a semiconductor structure including a first well region and a second well region, and forming a first and a second doping regions on an upper surface of the first well region; forming a groove on the first well region crossing from the first and to the second doping regions, with two sidewalls of the groove extending into the first and second doping regions; filing the groove to form a gate dielectric layer, and simultaneously forming a first dummy gate structure and a second dummy gate structure; simultaneously forming a first source region, a first drain region, a second source region, and a second drain region; replacing dummy gate layers within the first and second dummy gate structures with a first metal gate layer and a second metal gate layer, respectively; and forming electrodes.

### FIELD OF THE INVENTION

The present disclosure belongs to the field of semiconductor integrated circuit manufacturing, and in particular, relates to a semiconductor device and a manufacturing method thereof.

### BACKGROUND OF THE INVENTION

The shift toward larger screens and foldable displays in smartphones has significantly increased the demands for power efficiency and display performance in driver chips. Active-Matrix-Organic-Light-Emitting-Diode (AMOLED) displays, with their inherent advantages such as thin panels, vibrant color saturation, exceptional energy savings, low power consumption, and flexible display capabilities, have been positioned to become the preferred choice for mid-to-high-end smartphones in the future. Currently, AMOLED driver chips must integrate from low-voltage, high-speed devices for basic operations, high-voltage devices for thin-film transistor (TFT) drive, to medium-voltage devices for circuit driving. FIG. 1 shows a schematic cross-sectional view of the medium and low voltage device regions in an AMOLED driver chip, including the substrate 01, medium-voltage well region 011, Lightly Doped Drain (LDD) doping region 0111, low-voltage well region 012, trench isolation structure 013, groove 014, medium-voltage source region 015, medium-voltage drain region 016, low-voltage source region 017, low-voltage drain region 018, first metal gate 02, medium-voltage gate oxide layer 021, second metal gate 022, low-voltage gate oxide layer 023, metal silicide layer 024, first sidewall 025, second sidewall 026, first interlayer dielectric layer 03, second interlayer dielectric layer 031, silicon nitride stress layer 032, medium-voltage source electrode 04, medium-voltage drain electrode 041, low-voltage source electrode 042, and low-voltage drain electrode 043. In the integration process of medium and low voltage devices, due to the thicker gate oxide layer for medium-voltage devices than that in the low-voltage device, the medium-voltage device region must first be etched to lower the surface of the medium-voltage well region before etching the low-voltage well region. Subsequently, the medium-voltage gate oxide layer is deposited to raise the medium-voltage gate area. To minimize gate-induced drain leakage (GIDL) current in medium-voltage devices, the sidewalls 025 and 026 of the medium-voltage devices are thickened, pushing the source/drain regions out so increasing the distance between these regions and the conductive channel. For low-voltage devices, sidewall thickening is unnecessary, however, sidewall 025 in the low-voltage devices is also thickened in the same process of depositing 025. Thus, after thickening the sidewalls, the thickened portions in the low-voltage regions must be removed. Additionally, because the source/drain doping process is performed after forming the medium-voltage gate oxide layer, the medium-voltage gate oxide layer must also be blocked during doping to avoid covering the doping regions, which requires additional photomasks and involves intricate steps, resulting in higher manufacturing costs.

Consequently, there is an urgent need for a semiconductor device manufacturing method that simplifies the integration process for medium and low voltage devices while reducing production costs.

### SUMMARY OF THE INVENTION

The present disclosure provides a semiconductor device and a manufacturing method thereof, which can solve the complex process steps and high costs involved in integrating low-voltage devices onto the same chip in existing technologies.

According to the first embodiment of the present disclosure, a method for manufacturing a semiconductor device is provided, the method comprises steps S1-S5.

Step S1 comprises: providing a semiconductor structure, configuring a first well region of a first dopant type and a second well region of the first dopant type arranged at an interval on an upper surface of the semiconductor structure, and forming a first doping region of a second dopant type and a second doping region of the second dopant type arranged at an interval on an upper surface of the first well region.

Step S2 comprises: forming a groove on the upper surface of the first well region crossing from the first doping region to the second doping region, such that two sidewalls of the groove extend into the first doping region and the second doping region, respectively.

Step S3 comprises: filing the groove to form a gate dielectric layer, and synchronously forming a first dummy gate structure and a second dummy gate structure, wherein the first dummy gate structure is located directly above a region between the first doping region and the second doping region and comprises the gate dielectric layer, and the second dummy gate structure is located on an upper surface of the second well region.

Step S4 comprises: synchronously forming a first source region of the second dopant type, a first drain region of the second dopant type, a second source region of the second dopant type, and a second drain region of the second dopant type. The first source region is located on an upper surface of the first doping region, the first drain region is located on an upper surface of the second doping region, and the second source region and the second drain region are respectively located at two sides of the second dummy gate structure on the upper surface of the second well region.

Step S5 comprises: replacing dummy gate layers within the first dummy gate structure and the second dummy gate structure with a first metal gate layer and a second metal gate layer, respectively, and forming electrodes electrically connected to the first source region, the first drain region, the first metal gate layer, the second source region, the second drain region, and the second metal gate layer, respectively.

Optionally, a protective layer is formed on the semiconductor structure to cover the upper surface of the semiconductor structure, and the groove penetrates through the protective layer.

Optionally, the first dummy gate structure comprises a first gate dielectric layer and a first dummy gate layer, the first gate dielectric layer at least comprises the gate dielectric layer, and the first dummy gate layer is located on an upper surface of the first gate dielectric layer, and an edge of the first dummy gate layer is spaced apart from an edge of the gate dielectric layer by a preset distance. The second dummy gate structure comprises a first structure and a second structure arranged at an interval, the first structure comprises a second dummy gate layer and a second gate dielectric layer, the second dummy gate layer is located on an upper surface of the second gate dielectric layer, the second structure comprises a third dummy gate layer 27 and the second gate dielectric layer, and the third dummy gate layer 27 is located on the upper surface of the second gate dielectric layer of the first structure near the first well region.

Optionally, a communal doping region of the second dopant type is formed on the upper surface of the second well region between the first structure and the second structure, and is one of the second source region and the second drain region.

Optionally, after forming the first dummy gate structure and the second dummy gate structure, before forming the first source region, the first drain region, the second source region, and the second drain region, the method further comprises: forming sidewall structures covering sidewalls of the first dummy gate layer, the second dummy gate layer, and the third dummy gate layer 27, respectively. The sidewall structure covering the sidewall of the first dummy gate layer has a thickness less than the preset distance between the edge of the first dummy gate layer and the edge of the gate dielectric layer.

Optionally, after forming the first source region, the first drain region, the second source region, and the second drain region, before replacing the dummy gate layers within the first dummy gate structure and the second dummy gate structure with the first metal gate layer and the second metal gate layer, the method further comprises: forming a stress layer to cover an exposed upper surface of the semiconductor structure and exposed sidewalls of the first dummy gate structure and the second dummy gate structure.

Optionally, after forming the first source region, the first drain region, the second source region, and the second drain region, before replacing the dummy gate layers within the first dummy gate structure and the second dummy gate structure with the first metal gate layer and the second metal gate layer, the method further comprises: forming a first interlayer dielectric layer to cover the upper surface of the semiconductor structure. An upper surface of the first interlayer dielectric layer is flush with an upper surface of the first dummy gate structure and an upper surface of the second dummy gate structure.

Optionally, the first metal gate layer and the second metal gate layer are formed by: synchronously removing the dummy gate layers within the first dummy gate structure and the second dummy gate structure to obtain a first trench and a second trench located in the first interlayer dielectric layer; and synchronously filling the first trench and the second trench to obtain the first metal gate layer and the second metal gate layer.

Optionally, after forming the first metal gate layer and the second metal gate layer, before forming the electrodes, the method further comprises: forming a second interlayer dielectric layer to cover exposed upper surfaces of the first interlayer dielectric layer, the first metal gate layer, and the second metal gate layer.

A second embodiment of the present disclosure provides a semiconductor device, comprising a semiconductor structure, a first doping region of a second dopant type, a second doping region of the second dopant type, a groove, a gate dielectric layer, a first metal gate layer, a second metal gate layer, a first source region of the second dopant type, a first drain region of the second dopant type, a second source region of the second dopant type, a second drain region of the second dopant type, and electrodes.

An upper surface of the semiconductor structure is configured with a first well region of a first dopant type and a second well region of the first dopant type arranged at an interval.

The first doping region and the second doping region are arranged at an interval on an upper surface of the first well region.

The groove is located on the upper surface of the first well region between the first doping region and the second doping region. Two sidewalls of the groove extend into the first doping region and the second doping region, respectively.

The gate dielectric layer is obtained by filing the groove.

The first metal gate layer is located above the gate dielectric layer, and the gate dielectric layer is located directly above a region between the first doping region and the second doping region.

The second metal gate layer is located directly above the second well region.

The first source region and the first drain region are located on an upper surface of the first doping region and an upper surface of the second doping region, respectively.

The second source region and the second drain region are located at two sides of the second metal gate layer on the upper surface of the second well region, respectively.

The electrodes are electrically connected to the first source region, the first drain region, the first metal gate layer, the second source region, the second drain region, and the second metal gate layer, respectively.

As described above, the presently disclosed method directly forms the groove on the upper surface of the first well region, with two opposing sidewalls of the groove respectively extending into the first doping region and the second doping region. The protective layer acts as a barrier layer, enabling the formation of the gate dielectric layer by filling the groove. The presently disclosed method eliminates the need for a photomask to cover the gate dielectric layer on the upper surface of the first well region, as well as the subsequent photomask for etching the gate dielectric layer, omitting the step of etching the gate dielectric layer before forming the first source region and the first drain region, significantly reducing complexity and cost. Moreover, the sidewalls of the gate dielectric layer extend into the first and second doping regions, serving as barriers for injected ions forming the first source and drain regions, increasing the effective length of the conductive channel, reducing the electric field at the junctions between the conductive channel and the doping regions, and minimizing the Gate-Induced Drain Leakage Current (GIDL). Without the need for thick sidewalls, the manufacturing process is further simplified by removing the step of creating the photomasks for etching thick sidewalls, which ultimately lowers costs and adds significant industrial value.

### BRIEF DESCRIPTION OF DRAWINGS

FIG. 1 is a schematic cross-sectional view of medium and low voltage device regions of an AMOLED driver chip.

FIG. 2 is a flow chart of a method for manufacturing a semiconductor device according to the present disclosure.

FIG. 3 is a schematic cross-sectional view of an intermediate structure obtained after forming wells and a protective layer according to the present disclosure.

FIG. 4 is a schematic cross-sectional view of an intermediate structure obtained after forming a first doping region and a second doping region according to the present disclosure.

FIG. 5 is a schematic cross-sectional view of an intermediate structure obtained after forming a groove according to the present disclosure.

FIG. 6 is a schematic cross-sectional view of an intermediate structure obtained after forming a gate dielectric layer according to the present disclosure.

FIG. 7 is a schematic cross-sectional view of an intermediate structure obtained after forming a first dummy gate layer, a second dummy gate layer and a third dummy gate layer according to the present disclosure.

FIG. 8 is a schematic cross-sectional view of an intermediate structure obtained after forming sidewall structures according to the present disclosure.

FIG. 9 is a schematic cross-sectional view of an intermediate structure obtained after forming a first source region, a first drain region, a second source region, and a second drain region according to the present disclosure.

FIG. 10 is a schematic cross-sectional view of an intermediate structure obtained after forming a first interlayer dielectric layer according to the present disclosure.

FIG. 11 is a schematic cross-sectional view of an intermediate structure obtained after removing the first dummy gate layer, the second dummy gate layer, and the third dummy gate layer according to the present disclosure.

FIG. 12 is a schematic cross-sectional view of an intermediate structure obtained after forming metal gates and electrodes according to the present disclosure.

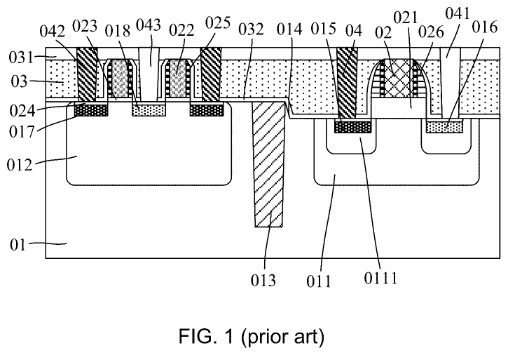

### Reference Numerals

01 Substrate

011 Medium-voltage well region

0111 LDD doping region

012 Low-voltage well region

013 Trench isolation structure

014 Groove

015 Medium-voltage source region

016 Medium-voltage drain region

017 Low-voltage source region

018 Low-voltage drain region

02 First metal gate

021 Medium-voltage gate oxide layer

022 Second metal gate

023 Low-voltage gate oxide layer

024 Metal silicide layer

025 First sidewall

026 Second sidewall

03 First interlayer dielectric layer

031 Second interlayer dielectric layer

032 Silicon nitride stress layer

04 Medium-voltage source

041 Medium-voltage drain

042 Low-voltage source

043 Low-voltage drain

1 Semiconductor structure

10 Protective layer

11 First well region

111 First doping region

112 Second doping region

12 Second well region

13 Isolation structure

14 Groove

15 Gate dielectric layer

16 First source region

17 First drain region

18 Second source region

19 Second drain region

2 First dummy gate structure

21 First dummy gate layer

22 First gate dielectric layer

23 Second dummy gate structure

24 Second dummy gate layer

25 Second gate dielectric layer

26 Metal silicide layer

27 Third dummy gate layer

3 Sidewall structure

31 Stress layer

4 First interlayer dielectric layer

41 First metal gate layer

42 Second metal gate layer

43 Second interlayer dielectric layer

5 First source electrode

51 First drain electrode

52 Second source electrode

53 Second drain electrode

### DETAILED DESCRIPTION OF THE INVENTION

The embodiments of the present disclosure will be described below. Those skilled can easily understand disclosure advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

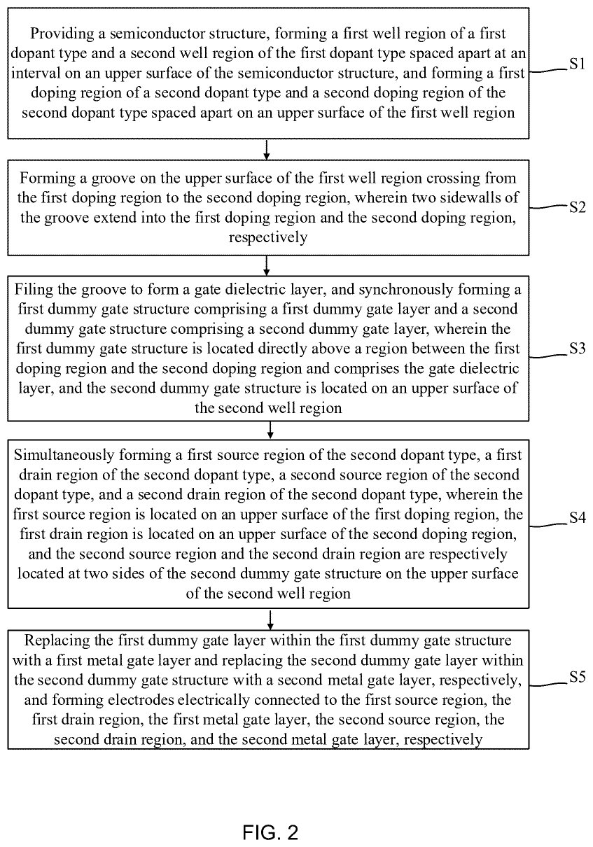

Refer to FIGS. 2 to 12. It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components'layout may also be more complicated.

### Embodiment 1

Embodiment 1 provides a method for manufacturing a semiconductor device, comprising steps S1-S5. FIG. 2 shows a flow chart of the method for manufacturing the semiconductor device.

Step S1 comprises: providing a semiconductor structure, configuring a first well region of a first dopant type and a second well region of the first dopant type arranged at an interval on an upper surface of the semiconductor structure, and forming a first doping region of a second dopant type and a second doping region of the second dopant type arranged at an interval on an upper surface of the first well region.

Step S2 comprises: forming a groove on the upper surface of the first well region crossing from the first doping region to the second doping region, such that two sidewalls of the groove to extend into the first doping region and the second doping region, respectively.

Step S3 comprises: filing the groove to form a gate dielectric layer, and synchronously forming a first dummy gate structure and a second dummy gate structure. The first dummy gate structure is located directly above a region between the first doping region and the second doping region and comprises the gate dielectric layer, and the second dummy gate structure is located on an upper surface of the second well region.

Step S4 comprises: synchronously forming a first source region of the second dopant type, a first drain region of the second dopant type, a second source region of the second dopant type, and a second drain region of the second dopant type. The first source region is located on an upper surface of the first doping region, the first drain region is located on an upper surface of the second doping region, and the second source region and the second drain region are respectively located at two sides of the second dummy gate structure on the upper surface of the second well region.

Step S5 comprises: replacing dummy gate layers within the first dummy gate structure and the second dummy gate structure with a first metal gate layer and a second metal gate layer, respectively, and forming electrodes electrically connected to the first source region, the first drain region, the first metal gate layer, the second source region, the second drain region, and the second metal gate layer, respectively.

FIGS. 3-5 illustrate various intermediate structures obtained after performing steps S1 and S2. Specifically, step S1 comprises: providing a semiconductor structure 1, configuring a first well region 11 of a first dopant type and a second well region 12 of the first dopant type arranged at an interval on an upper surface of the semiconductor structure 1, and forming a first doping region 111 of a second dopant type and a second doping region 112 of the second dopant type arranged at an interval on an upper surface of the first well region 11; step S2 comprises: forming a groove 14 on the upper surface of the first well region 11 crossing from the first doping region 111 to the second doping region 112, such that two sidewalls of the groove 14 extend into the first doping region 111 and the second doping region 112, respectively.

Specifically, the first doping type selects from one of N-type and P-type, and the second doping type selects from the other one of N-type and P-type, that is, the first doping type and the second doping type have different doping types.

The semiconductor structure 1 is typically a wafer used for fabricating integrated medium-voltage, high-voltage, and low-voltage devices, and the size, shape, thickness, and configuration thereof can be adjusted to suit practical requirements.

The upper surface of the first well region 11 is flush with an upper surface of the second well region 12. The first well region 11 is used for fabricating medium-voltage devices in the semiconductor device, and the second well region 12 is used for fabricating low-voltage devices in the semiconductor device.

The semiconductor structure 1 is further provided with an isolation structure 13, the isolation structure 13 is located between the first well region 11 and the second well region 12, and the isolation structure 13 is spaced apart from the first well region 11 and the second well region 12, respectively.

The isolation structure 13 comprises an isolation trench and an isolation layer, and the depth, the opening size and the opening shape of the isolation trench can be adjusted according to appropriate design rules under the condition of ensuring the performance of the semiconductor device.

The isolation layer is made of silicon oxide, silicon nitride, silicon oxynitride, or other suitable dielectric materials.

Under the condition that the performance of the semiconductor device is ensured, the distances between the isolation structure 13 and the first well region 11, as well as the second well region 12, can be adjusted according to appropriate design rules.

A protective layer 10 is formed on the semiconductor structure 1 to cover the upper surface of the semiconductor structure 1. The groove 14 penetrates through the protective layer 10.

It should be noted that, before forming the first well region 11 and the second well region 12 in the semiconductor structure 1, the protective layer 10 with a preset thickness is usually required to be formed on the upper surface of the semiconductor structure 1, so as to reduce damage to the active region in the semiconductor structure 1 in the process of forming the first well region 11 and the second well region 12.

FIG. 3 shows a schematic cross-sectional view of an intermediate structure obtained after forming the protective layer 10. The material of the protective layer 10 comprises silicon oxide, silicon nitride, or other suitable materials. Preferably, the protective layer 10 is a silicon nitride layer.

Under the condition that the performance of the semiconductor device is ensured, the thickness of the protective layer 10 can be adjusted according to appropriate design rules.

FIG. 4 shows a schematic cross-sectional view of an intermediate structure obtained after forming a first doping region 111 and a second doping region 112. The process of forming the first doping region 111 and the second doping region 112 arranged at an interval on the upper surface of the first well region 11 comprises ion implantation or other suitable methods. Preferably, the first doping region 111 and the second doping region 112 located in the first well region 11 are formed by an LDD implantation process. In Embodiment 1, a photoresist layer patterned for creating the first doping region 111 and the second doping region 112 is first formed on an upper surface of the protective layer 10, and then the LDD implantation process is performed based on this photoresist layer, to obtain the first doping region 111 and the second doping region 112.

It should be noted that, before forming the groove 14, a photoresist layer needs to be formed on the upper surface of the protective layer 10 first, then the photoresist layer is exposed based on a photomask designed for manufacturing the groove 14, and then the photoresist layer is developed to form a photoresist layer patterned for the groove 14, and then the protective layer 10 and the semiconductor structure 1 are etched based on the photoresist layer patterned for the groove 14, to produce the groove 14.

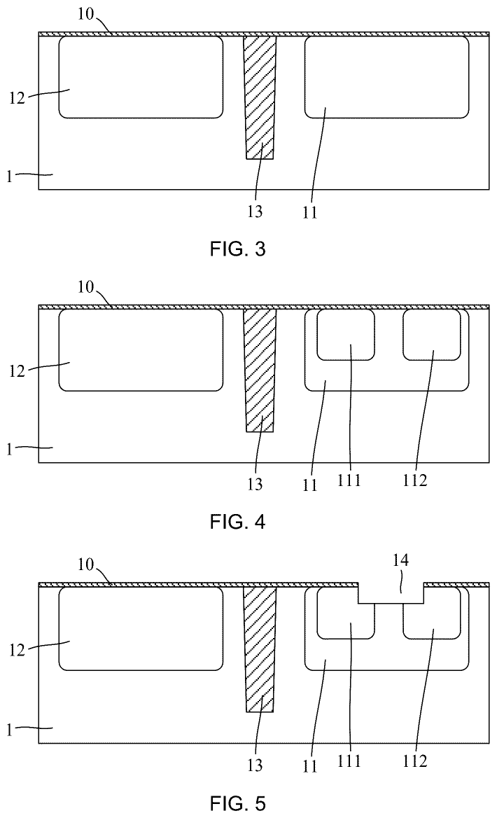

FIG. 5 shows a schematic cross-sectional view of an intermediate structure obtained after forming the groove 14. The process of forming the groove 14 comprises dry etching, wet etching, or other suitable methods.

Specifically, under the condition that the performance of the semiconductor device is ensured, the opening size and the opening shape of the groove 14 can be adjusted according to appropriate design rules. The distance between the sidewall of the groove 14 extending into the first doping region 111 and a sidewall of the first doping region 111 directly below the groove 14 can be adjusted according to appropriate design rules. The distance between the sidewall of the groove 14 extending into the second doping region 112 and a sidewall of the second doping region 112 directly below the groove 14 can be adjusted according to appropriate design rules.

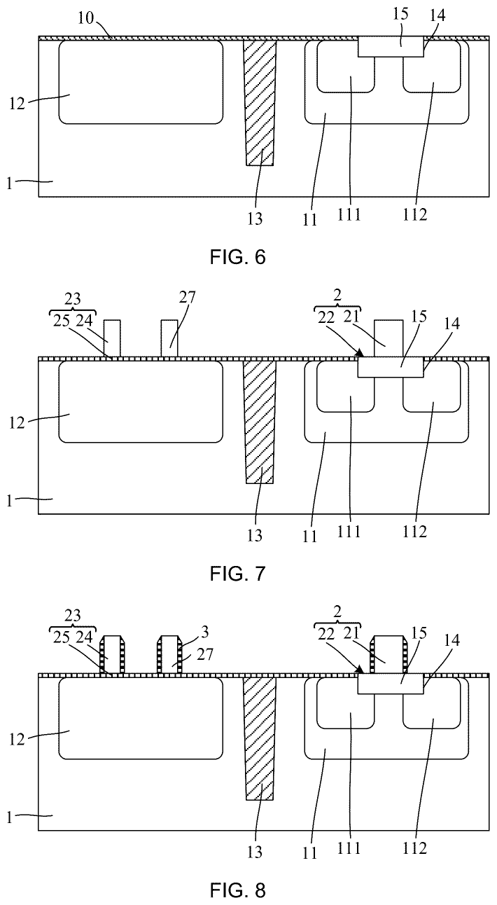

FIGS. 6-12 illustrate various intermediate structures obtained after performing steps S3, S4, and S5. Specifically, step S3 comprises: filing the groove 14 to form a gate dielectric layer 15, and synchronously forming a first dummy gate structure 2 and a second dummy gate structure 23; the first dummy gate structure 2 is located directly above a region between the first doping region 111 and the second doping region 112 and comprises the gate dielectric layer 15, and the second dummy gate structure 23 is located on the upper surface of the second well region 12; step S4 comprises: synchronously forming a first source region 16 of the second dopant type, a first drain region 17 of the second dopant type, a second source region 18 of the second dopant type, and a second drain region 19 of the second dopant type; the first source region 16 is located on an upper surface of the first doping region 111, the first drain region 17 is located on an upper surface of the second doping region 112, and the second source region 18 and the second drain region 19 are respectively located at two sides of the second dummy gate structure 23 on the upper surface of the second well region 12; step S5 comprises: replacing dummy gate layers within the first dummy gate structure 2 and the second dummy gate structure 23 with a first metal gate layer 41 and a second metal gate layer 42, respectively, and forming electrodes electrically connected to the first source region 16, the first drain region 17, the first metal gate layer 41, the second source region 18, the second drain region 19, and the second metal gate layer 42, respectively.

FIG. 6 shows a schematic cross-sectional view of an intermediate structure obtained after forming the gate dielectric layer 15. An upper surface of the gate dielectric layer 15 is flush with the upper surface of the first well region 11. The process of forming the gate dielectric layer 15 comprises chemical vapor deposition, physical vapor deposition, thermal oxidation, or other suitable methods. Preferably, the protective layer 10 is used as a barrier layer, and a thermal oxidation process is directly applied to form the gate dielectric layer 15 by filling the groove 14. In Embodiment 1, the protective layer 10 acts as a barrier layer, and a furnace tube oxidation process is directly applied to form the gate dielectric layer 15.

As an example, the first dummy gate structure 2 comprises a first gate dielectric layer 22 and a first dummy gate layer 21, the first gate dielectric layer 22 at least comprises the gate dielectric layer 15, and the first dummy gate layer 21 is located on an upper surface of the first gate dielectric layer 22, and an edge (i.e., sidewall) of the first dummy gate layer 21 is spaced apart from a corresponding one of edges (i.e., sidewalls) of the gate dielectric layer 15 by a preset distance.

As an example, the second dummy gate structure 23 comprises a first structure and a second structure arranged at an interval, the first structure comprises a second dummy gate layer 24 and a second gate dielectric layer 25, the second dummy gate layer 24 is located on an upper surface of the second gate dielectric layer 25, the second structure comprises a third dummy gate layer 27 located on the upper surface of the second gate dielectric layer 25, and the third dummy gate layer 27 is located on the upper surface of the second gate dielectric layer 25 of the first structure near the first well region 11.

Specifically, under the condition that the performance of the semiconductor device is ensured, the second dummy gate structure 23 may also have only one structure, that is, only the second dummy gate layer 24 and the second gate dielectric layer 25 are comprised in the second dummy gate structure 23. In embodiment 1, the second dummy gate structure 23 comprises two structures: the first structure and the second structure.

FIG. 7 is a schematic cross-sectional view of an intermediate structure obtained after forming a first dummy gate layer 21, a second dummy gate layer 24, and a third dummy gate layer 27. Since the first dummy gate structure 2 and the second dummy gate structure 23 are formed synchronously, along with the first dummy gate layer 21, the second dummy gate layer 24, and the third dummy gate layer 27, the protective layer 10 must first be removed after the gate dielectric layer 15 is formed, then the second gate dielectric layer 25 covering an exposed upper surface of the semiconductor structure 1 and the first gate dielectric layer 22 comprising the gate dielectric layer 15 are formed, and a dummy gate material layer is then deposited to cover exposed upper surfaces of the second gate dielectric layer 25 and the first gate dielectric layer 22. Finally, the dummy gate material layer is etched to obtain the first dummy gate structure 2 and the second dummy gate structure 23.

Specifically, after the protective layer 10 is removed, it is usually necessary to clean the exposed surface of the semiconductor structure 1 to remove any residues, and then the second gate dielectric layer 25 is formed, achieving high-quality performance.

It should be noted that after cleaning the exposed surface of the semiconductor structure 1, Advanced Process Control (APC) is utilized to make the heights of the upper surfaces of the gate dielectric layer 15 and the isolation layer more uniform (approaching level). Subsequently, a dry oxygen oxidation process is directly applied to form a low-pressure thin oxide layer, followed by the formation of a low-pressure gate oxide layer through a wet oxygen oxidation process (i.e., In-Situ Steam Generation, ISSG). Finally, a high-k dielectric layer is deposited to cover the upper surfaces of the low-pressure gate oxide layer and the gate dielectric layer 15, resulting in the second gate dielectric layer 25 and the first gate dielectric layer 22. The second gate dielectric layer 25 is composed of sequentially stacked layers, including the low-pressure thin oxide layer, the low-pressure gate oxide layer, and the high-k dielectric layer, above the first well region 11, while the first gate dielectric layer 22 consists of the gate dielectric layer 15 and the high-k dielectric layer covering the upper surface of the gate dielectric layer 15. Here, the high-k dielectric layer refers to a dielectric layer with a high dielectric constant.

The process of forming the high-k dielectric layer comprises atomic layer deposition, atomic vapor deposition, magnetron sputtering, or other suitable methods.

It should be noted that, before etching the dummy gate material layer, a hard mask layer covering an upper surface of the dummy gate material layer and a photoresist layer covering an upper surface of the hard mask layer are formed, and then the photoresist layer patterned by the photomask is exposed and developed for manufacturing the first dummy gate structure 2 and the second dummy gate structure 23, to obtain a photoresist layer patterned for the first dummy gate structure 2 and the second dummy gate structure 23, and then the hard mask layer and the dummy gate material layer are etched based on the photoresist layer patterned for the first dummy gate structure 2 and the second dummy gate structure 23, to obtain the first dummy gate structure 2 and the second dummy gate structure 23. The first dummy gate layer 21 is a composite film layer formed by sequentially stacked dummy gate material layer and hard mask layer above the first gate dielectric layer 22. The second dummy gate layer 24 and the third dummy gate layer 27 are composite film layers formed by sequentially stacked dummy gate material layer and hard mask layer on the upper surface of the second gate dielectric layer 25 above the second well region 12. The third dummy gate layer 27 and the second dummy gate layer 24 have the same structure and are arranged at an interval above the second well region 12. Under the condition that the performance of the semiconductor device is ensured, the first dummy gate layer 21 may also be only the remaining dummy gate material layer above the first gate dielectric layer 22, and the second dummy gate layer 24 and the third dummy gate layer 27 may also be remaining dummy gate material layers arranged at an interval on the upper surface of the second gate dielectric layer 25 above the second well region 12. In Embodiment 1, the first dummy gate layer 21, the second dummy gate layer 24, and the third dummy gate layer 27 are all composite film layers comprising a hard mask layer.

The material of the dummy gate material layer comprises amorphous silicon or other suitable materials, and the material of the hard mask layer comprises silicon oxide, silicon nitride, or other suitable materials. Preferably, the dummy gate material layer is an amorphous silicon layer, and the hard mask layer is a composite film layer composed of silicon oxide and silicon nitride.

Specifically, dimensions of the first dummy gate layer 21 are smaller than dimensions of the gate dielectric layer 15, under the condition that the performance of the semiconductor device is ensured, the distance between the edge of the first dummy gate layer 21 and the corresponding edge of the gate dielectric layer 15 can be adjusted according to appropriate design rules; and the distance between the second dummy gate layer 24 and the third dummy gate layer 27 can be adjusted according to appropriate design rules. The dimensions, shapes, and thicknesses of the first dummy gate layer 21, the second dummy gate layer 24, and the third dummy gate layer 27 can be adjusted according to appropriate design rules.

FIG. 8 is a schematic cross-sectional view of an intermediate structure obtained after forming sidewall structures 3. After forming the first dummy gate structure 2 and the second dummy gate structure 23, before forming the first source region 16, the first drain region 17, the second source region 18, and the second drain region 19, the method further comprises: forming the sidewall structures 3 covering the sidewalls of the first dummy gate layer 21, the second dummy gate layer 24, and the third dummy gate layer 27, respectively. The sidewall structure 3 covering the sidewall of the first dummy gate layer 21 has a thickness less than the preset distance between the edge of the first dummy gate layer 21 and the corresponding edge of the gate dielectric layer 15. The thickness herein refers to a distance from a surface of the corresponding sidewall structure 3 adjacent to the sidewall of the first dummy gate layer 21 to another surface of the corresponding sidewall structure 3 facing away from the sidewall of the first dummy gate layer 21.

Specifically, the sidewall structures 3 are formed by: forming a first sidewall material layer covering the exposed side surfaces of the first dummy gate layer 21, the exposed side surfaces of the second dummy gate layer 24 and the third dummy gate layer 27, as well as the exposed upper surfaces of the first gate dielectric layer 22 and the second gate dielectric layer 25; etching the first sidewall material layer to obtain first sidewall layers covering the sidewalls of the first dummy gate layer 21, the second dummy gate layer 24, and the third dummy gate layer 27, respectively; forming a photoresist layer patterned for a low-voltage device lightly doped drain region, and performing lightly doped drain on regions on both sides of the second dummy gate layer 24 and the third dummy gate layer 27 based on the photoresist layer patterned for the low-voltage device lightly doped drain region to obtain a lightly doped drain region of the second dopant type, with sidewalls extending into regions below the second dummy gate layer 24 and the third dummy gate layer 27, respectively; removing the photoresist layer patterned for the low-voltage device lightly doped drain region; forming a second sidewall material layer covering the exposed upper surfaces of the second gate dielectric layer 25 and the first gate dielectric layer 22 and the exposed surfaces of the first sidewall layers; and then etching the second sidewall material layer to obtain second sidewall layers covering the exposed surfaces of the first sidewall layers. The first sidewall layers and the second sidewall layers form the sidewall structures 3.

It should be noted that, the sidewall structure 3 of the first dummy gate layer 21 is usually located directly above the gate dielectric layer 15, the material of the first sidewall material layer comprises SiCN or other suitable materials, the material of the second sidewall material layer comprises silicon oxide, silicon nitride, or other suitable materials. The thicknesses of the first sidewall material layer and the second sidewall material layer can be adjusted according to appropriate design rules. Preferably, the first sidewall material layer is an SiCN layer, and the second sidewall material layer has a laminated structure comprising a silicon oxide layer with a thickness of 10 Å-45 Å and a silicon nitride stack layer with a thickness of 150 Å-300 Å. In Embodiment 1, the second sidewall material layer is formed by stacking a silicon oxide layer with a thickness of 20 Å and a silicon nitride layer with a thickness of 200 Å.

The method for forming the first sidewall material layer and the second sidewall material layer is a common sidewall material manufacturing method, and details are not described herein again.

Specifically, under the condition that the performance of the semiconductor device is ensured, the thicknesses of the first sidewall layers can be adjusted according to appropriate design rules; the doping concentration and thickness of the lightly doped drain region can be adjusted according to appropriate design rules; the distance between the sidewalls of the lightly doped drain region extending to an region directly below the second dummy gate layer 24 and the third dummy gate layer 27 can be adjusted according to appropriate design rules; the thicknesses of the second sidewall layers can be adjusted according to appropriate design rules; and the distance between the sidewall structure 3 covering the first dummy gate layer 21 and the corresponding edge of the gate dielectric layer 15 can be adjusted according to appropriate design rules.

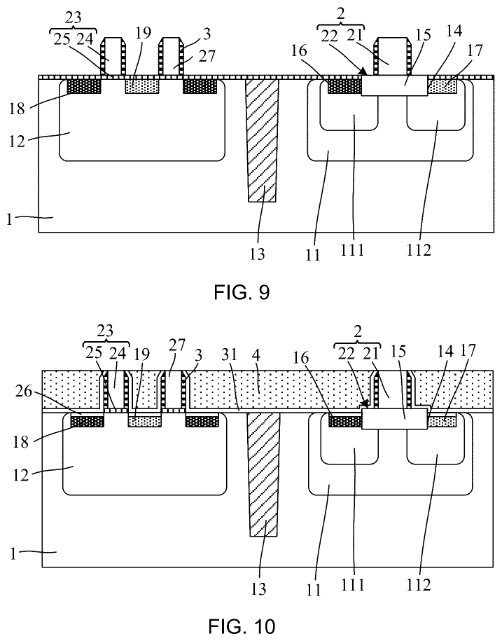

FIG. 9 is a schematic cross-sectional view of an intermediate structure obtained after forming the first source region 16, the first drain region 17, the second source region 18, and the second drain region 19. The process of synchronously forming the first source region 16, the first drain region 17, the second source region 18 and the second drain region 19 comprises ion implantation or other suitable methods. In Embodiment 1, a photoresist layer patterned for source-drain implantation is formed on an upper surface of the lightly doped drain region, and then ion implantation is performed on the exposed second well region 12, the first doping region 111, and the second doping region 112 based on the photoresist layer patterned for source-drain implantation, to obtain the second source region 18, the second drain region 19, the first source region 16, and the first drain region 17.

As an example, the lightly doped drain region formed on the upper surface of the second well region 12 between the first structure and the second structure serves as a communal doping region, and is one of the second source region 18 and the second doping region 19; that is, when the second dummy gate structure 23 comprises the first structure and the second structure, the lightly doped drain region on the upper surface can be shared.

Specifically, under the condition that the performance of the semiconductor device is ensured, two lightly doped drain regions may be formed within the second well region 12. These two lightly doped drain regions are respectively adjacent to the upper surface of the second well region 12, situated between the first structure and the second structure, and are arranged at an internal.

It should be noted that the first source region 16 is adjacent to a first sidewall of the gate dielectric layer 15 extending into the first doping region 111, the first drain region 17 is adjacent to a second sidewall of the gate dielectric layer 15 extending into the second doping region 112. When the second dummy gate structure 23 only comprises the second gate dielectric layer 25 and the second dummy gate layer 24, the second source region 18 and the second drain region 19 are respectively located on the upper surface of the second well region 12 on the two sides of the second dummy gate layer 24 and are respectively adjacent to the region directly below the second dummy gate layer 24.

Specifically, under the condition that the performance of the semiconductor device is ensured, the doping concentrations of the first source region 16, the first drain region 17, the second source region 18, and the second drain region 19 can be adjusted according to appropriate design rules; the dimensions, shapes, and thicknesses of the first source region 16, the first drain region 17, the second source region 18, and the second drain region 19 can be adjusted according to appropriate design rules.

As an example, after forming the first source region 16, the first drain region 17, the second source region 18, and the second drain region 19, before replacing the dummy gate layers within the first dummy gate structure 2 and the second dummy gate structure 23 with the first metal gate layer 41 and the second metal gate layer 42, the method further comprises: forming a stress layer 31 to cover an exposed upper surface of the semiconductor structure 1 and exposed sidewalls of the first dummy gate structure 2 and the second dummy gate structure 23. In Embodiment 1, the dummy gate layers within the first dummy gate structure 2 and the second dummy gate structure 23 comprise the first dummy gate layer 21, the second dummy gate layer 24, and the third dummy gate layer 27.

The material of the stress layer 31 comprises silicon nitride or other suitable stress materials. The process of forming the stress layer 31 is a common method for forming a stress material, and details are not described herein again.

Specifically, before forming the stress layer 31, it is necessary to remove the first gate dielectric layer 22, except for the regions directly below the second dummy gate layer 24 and the third dummy gate layer 27, and a metal silicide layer 26 is then formed to cover the upper surfaces of the first source region 16, the first drain region 17, the second source region 18 and the second drain region 19, effectively reducing the contact resistance between each of the electrodes and its corresponding region in the following process.

It should be noted that, when forming the metal silicide layer 26 located on the upper surfaces of the first source region 16 and the first drain region 17, the gate dielectric layer 15 may be used as a barrier layer, so that the effective distances from a first source electrode 5 and a first drain electrode 51 to a conductive channel subsequently manufactured become larger.

FIG. 10 is a schematic cross-sectional view of an intermediate structure obtained after forming a first interlayer dielectric layer 4. After forming the first source region 16, the first drain region 17, the second source region 18, and the second drain region 19, before replacing the dummy gate layers within the first dummy gate structure 2 and the second dummy gate structure 23 with the first metal gate layer 41 and the second metal gate layer 42, the method further comprises: forming the first interlayer dielectric layer 4 to cover the upper surface of the semiconductor structure. An upper surface of the first interlayer dielectric layer 4 is flush with the upper surfaces of the first dummy gate structure 2 and the second dummy gate structure 23.

It should be noted that, in the process of forming the first interlayer dielectric layer 4, an interlayer dielectric material layer whose upper surface is higher than the upper surfaces of the first dummy gate structure 2 and the second dummy gate structure 23 is usually first formed, and then this interlayer dielectric material layer is thinned by a chemical mechanical polishing process to obtain the first interlayer dielectric layer 4 whose upper surface is flush with the upper surfaces of the first dummy gate structure 2, the second dummy gate structure 23, and the stress layer 31.

The process of forming the interlayer dielectric material layer comprises chemical vapor deposition, physical vapor deposition, or other suitable methods; the material of the first interlayer dielectric layer 4 comprises silicon oxide, silicon nitride, silicon oxynitride, or other suitable dielectric materials. Preferably, the first interlayer dielectric layer 4 is a silicon oxide layer.

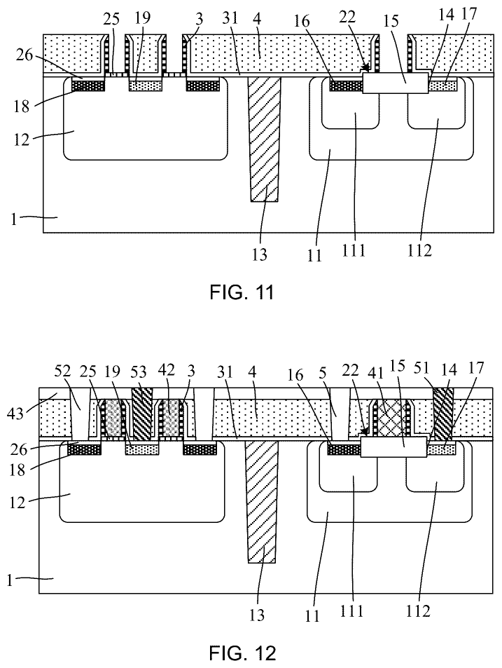

FIG. 11 is a schematic cross-sectional view of an intermediate structure obtained after removing the first dummy gate layer 21, the second dummy gate layer 24, and the third dummy gate layer 27. The first metal gate layer 41 and the second metal gate layer 42 are formed by: synchronously removing the dummy gate layers within the first dummy gate structure 2 and the second dummy gate structure 23 to obtain a first trench and a second trench located in the first interlayer dielectric layer 4; and synchronously filling the first trench and the second trench to obtain the first metal gate layer 41 and the second metal gate layer 42.

It should be noted that, before removing the dummy gate layers within the first dummy gate structure 2 and the second dummy gate structure 23, a photoresist layer patterned for the first metal gate layer 41 and the second metal gate layer 42 needs to be formed first, and then the dummy gate layer (the first dummy gate layer 21) in the first dummy gate structure 2 and the dummy gate layers (the second dummy gate layer 24 and the third dummy gate layer 27) in the second dummy gate structure 23 are removed based on this photoresist layer, to obtain the first trench using the upper surface of the first gate dielectric layer 22 as a bottom surface and the second trench using the upper surface of the second gate dielectric layer 25 as a bottom surface; and removing the photoresist layer.

Specifically, the process of removing the dummy gate layers within the first dummy gate structure 2 and the second dummy gate structure 23 comprises dry etching, wet etching, or other suitable methods; and the process of forming/removing the photoresist layer patterned for the first metal gate layer 41 and the second metal gate layer 42 can be a common photoresist patterning and stripping method.

It should be noted that, in a process of forming the first metal gate layer 41 and the second metal gate layer 42, a metal gate material layer needs to be formed first, to fill the first trench and the second trench and cover the upper surface of the first interlayer dielectric layer 4, and then the metal gate material layer covering the upper surface of the first interlayer dielectric layer 4 is removed to obtain the first metal gate layer 41 and the second metal gate layer 42.

Specifically, the process of forming the metal gate material layer comprises magnetron sputtering, physical vapor deposition, chemical vapor deposition, metal compound vapor deposition, molecular beam epitaxy, atomic vapor deposition, atomic layer deposition, or other suitable methods; the process of removing the metal gate material layer covering the upper surface of the first interlayer dielectric layer 4 comprises chemical mechanical polishing or other suitable methods.

Specifically, the materials of the first metal gate layer 41 and the second metal gate layer 42 are related to the doping types of the first well region 11 and the second well region 12.

As an example, after forming the first metal gate layer 41 and the second metal gate layer 42, before forming the electrodes, the method further comprises: forming a second interlayer dielectric layer 43 to cover exposed upper surfaces of the first interlayer dielectric layer 4, the first metal gate layer 41, and the second metal gate layer 42.

Specifically, the process of forming the second interlayer dielectric layer 43 comprises chemical vapor deposition, physical vapor deposition, or other suitable methods.

The material of the second interlayer dielectric layer 43 comprises silicon oxide, silicon nitride, silicon oxynitride, or other suitable materials. Preferably, the first interlayer dielectric layer 4 is made of the same material as the second interlayer dielectric layer 43.

FIG. 12 is a schematic cross-sectional view of an intermediate structure obtained after forming the electrodes. After forming the second interlayer dielectric layer 43, before forming the electrodes consisting of a first source electrode 5, a first drain electrode 51, a first gate electrode, a second source electrode 52, a second drain electrode 53, and a second gate electrode, the method further comprises: forming a first contact hole, a second contact hole, a third contact hole, a fourth contact hole, a fifth contact hole, and a sixth contact hole. The first contact hole penetrates through the first interlayer dielectric layer 4, the second interlayer dielectric layer 43 and the stress layer 31, with its lower surface revealing the metal silicide layer 26 located on the upper surface of the first source region 16. The second contact hole penetrates through the first interlayer dielectric layer 4, the second interlayer dielectric layer 43 and the stress layer 31, with its lower surface revealing the metal silicide layer 26 located on the upper surface of the first drain region 17. The third contact hole penetrates through the second interlayer dielectric layer 43 located directly above the first metal gate layer 41, with its lower surface revealing the first metal gate layer 41. The fourth contact hole penetrates through the first interlayer dielectric layer 4, the second interlayer dielectric layer 43 and the stress layer 31, with its lower surface revealing the metal silicide layer 26 located on the upper surface of the second source region 18. The fifth contact hole penetrates through the first interlayer dielectric layer 4, the second interlayer dielectric layer 43 and the stress layer 31, with its lower surface revealing the metal silicide layer 26 located on the upper surface of the second drain region 19. The sixth contact hole penetrates through the second interlayer dielectric layer 43 located directly above the second metal gate layer 42, with its lower surface revealing the second metal gate layer 42.

Specifically, the first source electrode 5 fills the first contact hole and is electrically connected to the first source region 16 through the metal silicide layer 26 on the upper surface of the first source region 16. The first drain electrode 51 fills the second contact hole and is electrically connected to the first drain region 17 through the metal silicide layer 26 on the upper surface of the first drain region 17. The first gate electrode fills the third contact hole and is electrically connected to the first metal gate layer 41 of the first dummy gate structure 2. The second source electrode 52 fills the fourth contact hole and is electrically connected to the second source region 18 through the metal silicide layer 26 on the upper surface of the second source region 18. The second drain electrode 53 fills the fifth contact hole and is electrically connected to the second drain region 19 through the metal silicide layer 26 on the upper surface of the second drain region 19. The second gate electrode fills the sixth contact hole and is electrically connected to the second metal gate layer 42 of the second dummy gate structure 23.

Specifically, the process of forming the contact holes (first to sixth contact holes) comprises dry etching, wet etching, or other suitable methods.

Specifically, the process of forming the electrodes comprises magnetron sputtering, physical vapor deposition, chemical vapor deposition, metal compound vapor deposition, molecular beam epitaxy, atomic vapor deposition, atomic layer deposition, or other suitable methods.

The presently disclosed method directly forms the groove 14 on the upper surface of the first well region 11 between the first doping region 111 and the second doping region 112, with two opposing sidewalls of the groove 14 respectively extending into the first doping region and the second doping region. The protective layer 10 acts as a barrier layer, enabling the formation of the gate dielectric layer 15 by filling the groove 14. The presently disclosed method eliminates the need for a photomask to cover the gate dielectric layer 15 on the upper surface of the first well region 11, as well as the subsequent photomask for etching the gate dielectric layer 15, omitting the step of etching the gate dielectric layer 15 before forming the first source region 16 and the first drain region 17, significantly reducing complexity and cost.

Specifically, outside the sidewall structure 3, there is another sidewall which also covers the sidewall structure 3 of the first dummy gate structure 2, this other sidewall is spaced apart from the outer edge of the gate dielectric layer 15 by a preset distance, so that the space between the conductive channels in the first well region 11 can be increased, if the gate dielectric layer 15 is blocked during the implantation of the first source region 16 and the first drain region 17, as a result, formation of a thick sidewall structure 3 is prevented, thereby reducing the electric field at the junctions between the conductive channel and the doping regions, and minimizing the GIDL. Without the need for thick sidewalls used to extrapolate the first source region 16 and the first drain region 17, the manufacturing process is further simplified by saving photomasks for thick sidewalls, which ultimately lowers costs and adds significant industrial value.

By improving the manufacturing process, after forming the first doping region 111 and the second doping region 112 arranged at an interval on the upper surface of the first well region 11, the groove 14 is directly formed on the upper surface of the first well region 11, with two opposing sidewalls of the groove 14 respectively extend into the first doping region 111 and the second doping region 112. The protective layer 10 acts as a barrier layer, enabling the formation of the gate dielectric layer 15 by filling into the groove 14. The presently disclosed method eliminates the need for a photomask to cover the gate dielectric layer 15 on the upper surface of the first well region 11, as well as the subsequent photomask for etching the gate dielectric layer 15, skipping the step of etching the gate dielectric layer 15 before forming the first source region 16 and the first drain region 17, thus, significantly reducing process complexity and cost. Moreover, the sidewalls of the gate dielectric layer 15 can extend into the first and second doping regions, serving as barriers against ions injecting into the first source region 16 and the second drain region 19 from implantation, thereby increasing the effective length of the conductive channel, reducing the electric field at the junctions between the conductive channel and the doping regions, and minimizing the GIDL. Without the need for thick sidewalls, the manufacturing process is further simplified by saving photomasks for etching thick sidewalls, which ultimately lowers costs and adds significant industrial value.

### Embodiment 2

As shown in FIG. 12, the present disclosure further provides a semiconductor device, comprising a semiconductor structure 1, a first doping region 111 of a second dopant type, a second doping region 112 of the second dopant type, a groove 14, a gate dielectric layer 15, a first metal gate layer 41, second metal gate layer 42 (the third dummy gate 27 is replaced with the second metal gate layer 42 in a similar process as the second dummy gate layer 24 is), a first source region 16 of the second dopant type, a first drain region 17 of the second dopant type, a second source region 18 of the second dopant type, a second drain region 19 of the second dopant type, and electrodes. An upper surface of the semiconductor structure 1 is configured with a first well region 11 of a first dopant type and a second well region 12 of the first dopant type arranged at an interval. The first doping region 111 and the second doping region 112 are arranged at an interval on an upper surface of the first well region 11.

The groove 14 is located on the upper surface of the first well region 11 crossing from the first doping region 111 to the second doping region 112, such that two sidewalls of the groove 14 extend into the first doping region 111 and the second doping region 112, respectively. The gate dielectric layer 15 is obtained by filing the groove 14. The first metal gate layer 41 is located above the gate dielectric layer 15, which, in turn, is situated directly above a region between the first doping region 111 and the second doping region 112. The second metal gate layers 42 are located directly above the second well region 12. The first source region 16 and the first drain region 17 are located on an upper surface of the first doping region 111 and an upper surface of the second doping region 112, respectively. The second source region 18 and the second drain region 19 are located at two sides of the second metal gate layers 42 on an upper surface of the second well region 12, respectively. The electrodes are electrically connected to the first source region 16, the first drain region 17, the first metal gate layer 41, the second source region 18, the second drain region 19, and the second metal gate layers 42, respectively.

It should be noted that the upper surface of the first well region 11 is flush with the upper surface of the second well region 12. The first well region 11 is part of the medium-voltage devices in the semiconductor device, and the second well region 12 is part of the low-voltage devices in the semiconductor device. The semiconductor structure 1 further comprises a well region as a part of the high-voltage devices (not shown in FIG. 12) in the semiconductor device, and the dimension, shape, doping concentration, and location thereof can be adjusted to suit practical requirements.

Under the condition that the performance of the semiconductor device is ensured, the doping concentrations, dimensions, and shapes of the first well region 11 and the second well region 12 can be adjusted according to appropriate design rules; the distance between the first well region 11 and the second well region 12 can be adjusted according to appropriate design rules. In Embodiment 2, the first well region 11 is a well region for manufacturing an 8V medium-voltage device.

The semiconductor structure 1 is further provided with an isolation structure 13, the isolation structure 13 is located on the upper surface of the semiconductor structure 1 between the first well region 11 and the second well region 12, and a bottom surface of the isolation structure 13 is lower than the bottom surfaces of the first well region 11 and the second well region 12. The isolation structure 13 is spaced apart from the first well region 11 and the second well region 12, respectively.

Specifically, under the condition that the performance of the semiconductor device is ensured, the doping concentrations, dimensions, shapes, and thicknesses of the first doping region 111 and the second doping region 112 can be adjusted according to appropriate design rules; the distance between the first doping region 111 and the second doping region 112 can be adjusted according to appropriate design rules. The thickness herein is the distance between the upper surface and the bottom surface of the first doping region 111 (or, the second doping region 112).

Specifically, the bottom surface of the groove 14 is higher than the bottom surfaces of the first doping region 111 and the second doping region 112, and the depth of the groove 14 ranges from 150 Å to 300 Å, for example, 180 Å, 220 Å, 250 Å, and 280 Å, preferably, the depth of the groove 14 is 200 Å. Under the condition that the performance of the semiconductor device is ensured, the depth of the groove 14 may also be another suitable value. The depth here refers to the distance between the bottom surface of the groove 14 and the opening of the groove 14.

Specifically, the upper surface of the gate dielectric layer 15 is flush with the upper surface of the first well region 11, and the material of the gate dielectric layer 15 comprises silicon oxide, silicon nitride, silicon oxynitride, or other suitable dielectric materials. Preferably, the gate dielectric layer 15 is a silicon oxide layer obtained by filling the groove 14.

Specifically, a high-k dielectric layer is further arranged below the first metal gate layer 41 to cover the upper surface of the gate dielectric layer 15, the first metal gate layer 41 is located on an upper surface of the high-k dielectric layer, and the high-k dielectric layer and the gate dielectric layer 15 are combined to jointly serve as the first gate dielectric layer 22 for isolating the first metal gate layer 41 and the semiconductor structure 1 below the groove 14.

Specifically, a second gate dielectric layer 25 is further disposed directly below the second metal gate layers 42, the second gate dielectric layer 25 is located on the upper surface of the second well region 12, the second metal gate layers 42 are located on an upper surface of the second gate dielectric layer 25, and the second gate dielectric layer 25 comprises a thin oxide layer, a low-voltage gate oxide layer, and a high-k dielectric layer that are sequentially stacked. The thicknesses of the thin oxide layer, the low-voltage gate oxide layer, and the high-k dielectric layer can be adjusted according to appropriate design rules.

As an example, the upper surface of the second well region 12 is provided with two second gate dielectric layers 25 arranged at an interval, and the upper surfaces of the two second gate dielectric layers 25 are respectively provided with second metal gate layers 42.

Generally, the work function of the first metal gate layer 41 needs to be matched with the doping type of the first well region 11, and the work function of the second metal gate layers 42 needs to be matched with the doping type of the second well region 12, so as to reduce the height of the Schottky barrier in contact with the well regions, therefore, the material of the first metal gate layer 41 and the material of the second metal gate layers 42 are related to the doping types of the well regions below the first metal gate layer 41 and the second metal gate layers 42.

The sidewalls of the first metal gate layer 41 and the second metal gate layers 42 are provided with sidewall structures 3, and an edge of the sidewall structure 3 covering the sidewall of the first metal gate layer 41 is spaced apart from a corresponding one of edges of the gate dielectric layer 15 by a preset distance.

Specifically, the first source region 16 and the first drain region 17 are adjacent to the two sidewalls of the gate dielectric layer 15, respectively, and the first source region 16 and the first drain region 17 may also be spaced apart from the sidewalls of the gate dielectric layer 15 in the case of ensuring device performance.

It should be noted that the electrical connection type of each of the electrodes and the corresponding region is in ohmic contact, that is, the contact type between the first source region 16 and the first source electrode 5, the first drain region 17 and the first drain electrode 51, the second source region 18 and the second source electrode 52, and the second drain region 19 and the second drain electrode 53 are all ohmic contacts.

Specifically, the upper surfaces of the first source region 16, the first drain region 17, the second source region 18, and the second drain region 19 are further provided with a metal silicide layer 26, to reduce the contact resistance between each of the electrodes (the first source electrode 5, the first drain electrode 51, the second source electrode 52, and the second drain electrode 53) and the corresponding region, and the material and the thickness of the metal silicide layer 26 can be adjusted according to appropriate design rules.

Specifically, a stress layer 31, a first interlayer dielectric layer 4 and a second interlayer dielectric layer 43 are further stacked on the semiconductor structure 1. The stress layer 31 covers the exposed upper surface of the semiconductor structure 1 and the exposed surfaces of the sidewall structures 3. The first interlayer dielectric layer 4 covers an upper surface of the stress layer 31, and an upper surface of the first interlayer dielectric layer 4 is flush with the upper surfaces of the first metal gate layer 41 and the second metal gate layers 42. The second interlayer dielectric layer 43 covers the upper surface of the first interlayer dielectric layer 4 and the exposed upper surfaces of the stress layer 31, the first metal gate layer 41, and the second metal gate layers 42.

Under the condition that the performance of the semiconductor device is ensured, the thickness and the stress type of the stress layer 31 can be adjusted according to appropriate design rules; the thickness of the second interlayer dielectric layer 43 can be adjusted according to appropriate design rules.

Specifically, the first source electrode 5 penetrates through the second interlayer dielectric layer 43, the first interlayer dielectric layer 4 and the stress layer 31 and is in contact with the metal silicide layer 26 on the upper surface of the first source region 16. The first drain electrode 51 penetrates through the second interlayer dielectric layer 43, the first interlayer dielectric layer 4 and the stress layer 31 and is in contact with the metal silicide layer 26 on the upper surface of the first drain region 17. The second source electrode 52 penetrates through the second interlayer dielectric layer 43, the first interlayer dielectric layer 4 and the stress layer 31 and is in contact with the metal silicide layer 26 on the upper surface of second source region 18. The second drain electrode 53 penetrates through the second interlayer dielectric layer 43, the first interlayer dielectric layer 4 and the stress layer 31 and is in contact with the metal silicide layer 26 on the upper surface of the second drain region 19.

Specifically, the material of each of the electrodes is a common metal electrode material.

By improving the device structure, the groove 14 is formed on the upper surface of the first well region 11 between the first doping region 111 and the second doping region 112, the two opposite sidewalls of the groove 14 respectively extend into the first doping region 111 and the second doping region 112, the gate dielectric layer 15 is obtained by filing the groove 14, streamlining the device manufacturing process and reducing production costs.

By improving the device structure, the groove 14 is directly formed on the upper surface of the first well region 11 between the first doping region 111 and the second doping region 112, with two opposing sidewalls of the groove 14 respectively extending into the first doping region 111 and the second doping region 112. The gate dielectric layer 15 is obtained using the groove 14, streamlining the device manufacturing process and reducing production costs.

As described above, the presently disclosed method directly forms the groove on the upper surface of the first well region, with two opposing sidewalls of the groove respectively extending into the first doping region and the second doping region. The protective layer acts as a barrier layer, enabling the formation of the gate dielectric layer by filling the groove. The presently disclosed method eliminates the need for a photomask to cover the gate dielectric layer on the upper surface of the first well region, as well as the subsequent photomask for etching the gate dielectric layer, omitting the step of etching the gate dielectric layer before forming the first source region and the first drain region, significantly reducing complexity and cost. Moreover, the sidewalls of the gate dielectric layer extend into the first and second doping regions, serving as barriers for injected ions forming the first source and drain regions, increasing the effective length of the conductive channel, reducing the electric field at the junctions between the conductive channel and the doping regions, and minimizing the GIDL. Without the need for thick sidewalls, the manufacturing process is further simplified by removing the step of creating the etching photomasks for thick sidewalls, which ultimately lowers costs and adds significant industrial value. Therefore, the present disclosure effectively overcomes various shortcomings of the prior art and has a high industrial value.

The above-mentioned embodiments are for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the scope of the present disclosure.

1. A method for manufacturing a semiconductor device, comprising:
S1: providing a semiconductor structure, forming a first well region of a first dopant type and a second well region of the first dopant type spaced apart at an interval on an upper surface of the semiconductor structure, and forming a first doping region of a second dopant type and a second doping region of the second dopant type spaced apart on an upper surface of the first well region;
S2: forming a groove on the upper surface of the first well region crossing from the first doping region to the second doping region, wherein two sidewalls of the groove extend into the first doping region and the second doping region, respectively;
S3: filing the groove to form a gate dielectric layer, and synchronously forming a first dummy gate structure comprising a first dummy gate layer and a second dummy gate structure comprising a second dummy gate layer, wherein the first dummy gate structure is located directly above a region between the first doping region and the second doping region and comprises the gate dielectric layer, and the second dummy gate structure is located on an upper surface of the second well region;
S4: simultaneously forming a first source region of the second dopant type, a first drain region of the second dopant type, a second source region of the second dopant type, and a second drain region of the second dopant type, wherein the first source region is located on an upper surface of the first doping region, the first drain region is located on an upper surface of the second doping region, and the second source region and the second drain region are respectively located at two sides of the second dummy gate structure on the upper surface of the second well region; and
S5: replacing the first dummy gate layer within the first dummy gate structure with a first metal gate layer and replacing the second dummy gate layer within the second dummy gate structure with a second metal gate layer, respectively, and forming electrodes electrically connected to the first source region, the first drain region, the first metal gate layer, the second source region, the second drain region, and the second metal gate layer, respectively.

2. The method according to claim 1, wherein a protective layer is formed on the semiconductor structure to cover the upper surface of the semiconductor structure, and wherein the groove penetrates through the protective layer.

3. The method according to claim 1, wherein the first dummy gate structure further comprises a first gate dielectric layer, wherein the first gate dielectric layer at least comprises the gate dielectric layer, and the first dummy gate layer is located on an upper surface of the first gate dielectric layer, and wherein an edge of the first dummy gate layer at one side is spaced apart from an edge of the first gate dielectric layer at a same side by a preset distance; wherein the second dummy gate structure further comprises a first structure and a second structure arranged at an interval, wherein the first structure comprises the second dummy gate layer and a second gate dielectric layer, wherein the second dummy gate layer is located on an upper surface of the second gate dielectric layer, wherein the second structure comprises a third dummy gate layer and the second gate dielectric layer, and wherein the third dummy gate layer is located on the upper surface of the second gate dielectric layer of the first structure near the first well region.

4. The method according to claim 3, wherein a communal doping region of the second dopant type is formed on the upper surface of the second well region between the first structure and the second structure, and includes the second source region and the second drain region.

5. The method according to claim 3, wherein after forming the first dummy gate structure and the second dummy gate structure in S3, and before forming the first source region, the first drain region, the second source region, and the second drain region in S4, the method further comprises: forming sidewall structures covering sidewalls of the first dummy gate layer, the second dummy gate layer, and the third dummy gate layer, wherein the sidewall structure covering the sidewalls of the first dummy gate layer has a thickness less than the preset distance between the edge of the first dummy gate layer and the edge of the gate dielectric layer at the same side.

6. The method according to claim 1, wherein after forming the first source region, the first drain region, the second source region, and the second drain region is S4, before replacing the first dummy gate layer within the first dummy gate structure with the first metal gate layer and replacing the second dummy gate layer within the second dummy gate structure with the second metal gate layer in S5, the method further comprises: forming a stress layer covering an exposed upper surface of the semiconductor structure and exposed sidewalls of the first dummy gate structure and the second dummy gate structure.

7. The method according to claim 1, wherein after forming the first source region, the first drain region, the second source region, and the second drain region in S4, before replacing the first dummy gate layer within the first dummy gate structure with the first metal gate layer and replacing the second dummy gate layer within the second dummy gate structure with the second metal gate layer in S5, the method further comprises: forming a first interlayer dielectric layer to cover the upper surface of the semiconductor structure, wherein an upper surface of the first interlayer dielectric layer is flush with an upper surface of the first dummy gate structure and an upper surface of the second dummy gate structure.

8. The method according to claim 7, wherein the first metal gate layer and the second metal gate layer are formed by:
simultaneously removing the first dummy gate layer from the first dummy gate structure and the second dummy gate layer from the second dummy gate structure to obtain a first trench and a second trench located in the first interlayer dielectric layer; and
simultaneously filling the first trench to obtain the first metal gate layer and filling the second trench to obtain the second metal gate layer.

9. The method according to claim 8, wherein after forming the first metal gate layer and the second metal gate layer, before forming the electrodes, the method further comprises: forming a second interlayer dielectric layer to cover exposed upper surfaces of the first interlayer dielectric layer, the first metal gate layer, and the second metal gate layer.

10. A semiconductor device, comprising:
a semiconductor structure, an upper surface of which is configured with a first well region of a first dopant type and a second well region of the first dopant type arranged at an interval;
a first doping region of a second dopant type and a second doping region of the second dopant type, arranged at an interval on an upper surface of the first well region;
a groove, located on the upper surface of the first well region crossing from the first doping region to the second doping region, wherein two sidewalls of the groove extend into the first doping region and the second doping region, respectively;
a gate dielectric layer, obtained by filing the groove with a gate dielectric material;
a first metal gate layer, located above the gate dielectric layer, wherein the gate dielectric layer is located directly above a region between the first doping region and the second doping region;
a second metal gate layer, located directly above the second well region;
a first source region of the second dopant type and a first drain region of the second dopant type, located on an upper surface of the first doping region and an upper surface of the second doping region, respectively;
a second source region of the second dopant type and a second drain region of the second dopant type, located at two sides of the second metal gate layer on the upper surface of the second well region, respectively; and
electrodes, electrically connected to the first source region, the first drain region, the first metal gate layer, the second source region, the second drain region, and the second metal gate layer, respectively.
